(19) United States
(12) Patent Application Publication
(10) Pub. No.: US 2021/0013405 A1
(43) Pub. Date: Jan. 14, 2021

(54) RESISTIVE SWITCHING NONVOLATILE RANDOM ACCESS MEMORY DEVICE

(71) Applicant: GLOBALFOUNDRIES Singapore Pte. Ltd., Singapore (SG)

(72) Inventors: DAO HWEE GRAYSON WONG, Singapore (SG); KAZUTAKA YAMANE, Singapore (SG); JU DY LIM, Singapore (SG); DINGGUI ZENG, Singapore (SG); CHIM SENG SEET, Singapore (SG)

(21) Appl. No.: 16/504,344

(22) Filed: Jul. 8, 2019

(51) Int. Cl. H01L 45/00

(52) U.S. Cl. CPC H01L 45/1246; H01L 45/08; H01L 27/2436; H01L 45/1253; H01L 45/16; H01L 45/1233

(57) ABSTRACT

The disclosure relates generally to resistive switching nonvolatile random access memory (ReRAM) devices, and more generally to structures and methods of fabricating multiple conductive elements in ReRAM devices. A resistive memory device is presented, the device comprising a first electrode having a first work function, and a second electrode having a second work function, the first work function being different from the second work function. A dielectric layer is disposed between the first and second electrodes. The device further comprises a set of nanocrystal structures distributed in the dielectric layer. A conductive layer is also disposed in the dielectric layer.

### FIELD OF THE INVENTION

The disclosed embodiments relate generally to resistive switching nonvolatile random access memory (ReRAM) devices, and more particularly, to structures and methods of forming multiple conductive elements in ReRAM devices.

### BACKGROUND

Nonvolatile memory elements are used in systems when “persistent” storage is required. For example, nonvolatile memory elements are used to persistently store data in computer environments. Digital cameras use nonvolatile memory elements to store image data and digital music players use nonvolatile memory elements to store audio data. Nonvolatile memory is often formed using electrically-erasable programmable read only memory (EEPROM) technology. An EEPROM device typically includes floating gate transistors that can be programmed or erased by application of program and erase voltages, respectively.

As device dimensions shrink, it becomes more challenging to fabricate traditional nonvolatile memory devices due to scaling issues. This has led to the investigation of alternative memory technologies, including ReRAM devices.

A ReRAM device uses reversible resistance switching between two different resistance states, a low resistance state and a high resistance state. The device is switched between the two different resistance states through the application of suitable switching voltages. The applied voltage causes the formation and breaking of conducting filaments across an insulating metal-oxide based dielectric layer that results in the low and high resistance states, respectively.

Over time, it becomes increasingly more difficult to switch the device from a high resistance state to a low resistance state or from a low resistance state to a high resistance state, i.e., set or reset, respectively. The number of repeated set and reset cycles that the device is able to reliably undergo determines the device lifetime. Naturally, it is desirable for the device to be able to undergo a large number of set and reset cycles.

In addition, a large variability is observed in the voltages required to switch the device for the set and reset voltages, respectively. A tight distribution in the set and reset voltages or switching voltages is desirable.

Hence, there is a need for a ReRAM structure that can meet the design criteria for advanced memory devices.

### SUMMARY

To achieve the foregoing and other aspects of the present disclosure, structures and a method of fabricating resistive memory devices with multiple conductive elements are presented.

According to an aspect of this disclosure, a resistive memory device is provided, which includes a first electrode having a first work function and a second electrode having a second work function, wherein the first work function is different from the second work function. A dielectric layer is disposed between the first and second electrodes. A set of nanocrystal structures is distributed in the dielectric layer and a conductive layer is disposed in the dielectric layer.

According to another aspect of this disclosure, a resistive memory device is provided, which includes a first electrode and a second electrode. A dielectric layer is disposed between the first and second electrodes. At least one set of nanocrystal structures is horizontally distributed in the dielectric layer. A conductive layer is horizontally disposed in the dielectric layer.

In yet another aspect of this disclosure, a method of fabricating a resistive memory device is provided, which includes depositing a layer of metal having a first work function to form a first electrode. A first dielectric layer is deposited on the first electrode. A first conductive layer is formed on the dielectric layer. A second dielectric layer is deposited on the first conductive layer. A second conductive layer is formed on the second dielectric layer. A third dielectric layer is deposited on the second conductive layer. A layer of metal having a second work function is deposited over the third dielectric layer to form a second electrode, wherein the first work function is different from the second work function.

Numerous advantages may be derived from the embodiments described below wherein a resistive memory device includes a set of nanocrystal structures distributed in a dielectric layer and a conductive layer disposed in the dielectric layer. The nanocrystal structures lead to a tighter distribution in set and reset voltages as well as the high and low resistance states. Tighter distributions in switching voltages and resistance states are achieved as the nanocrystal structures lead to conductive filament formation at particular locations in the device.

In an aspect of the present disclosure, the conductive layer may be a metal layer. In another aspect of the present disclosure, the conductive layer may be a set of nanocrystal structures distributed in a dielectric layer. The conductive layer leads to the formation of shorter filaments, hence allowing more control on the filament formation. The added control over the resistive memory device improves the device lifetime.

In a preferred embodiment, the conductive layer may be a set of nanocrystal structures distributed in a dielectric layer due to the advantages mentioned above. In another embodiment, the conductive layer may be a metal layer due to lower cost of fabrication.

### BRIEF DESCRIPTION OF THE DRAWINGS

The disclosed embodiments will be better understood from a reading of the following detailed description, taken in conjunction with the accompanying drawings:

FIG. 1 is a cross-section view of a resistive memory device according to an embodiment of the disclosure.

FIG. 2 is a cross-section view of a resistive memory device according to another embodiment of the disclosure.

FIG. 3 is a cross-section view of a resistive memory device according to yet another embodiment of the disclosure.

FIG. 4 is a cross-section view of a resistive memory device according to another embodiment of the disclosure.

FIG. 5 is a cross-section view of a resistive memory device according to another embodiment of the disclosure.

FIG. 6 is a cross-section view of a resistive memory device according to another embodiment of the disclosure.

FIG. 7 is a cross-section view of a resistive memory device according to another embodiment of the disclosure.

FIG. 8 is a cross-section view of a resistive memory device according to another embodiment of the disclosure.

FIG. 9 is a cross-section view of a resistive memory device according to another embodiment of the disclosure.

For simplicity and clarity of illustration, the drawings illustrate the general manner of construction, and certain descriptions and details of well-known features and techniques may be omitted to avoid unnecessarily obscuring the discussion of the described embodiments of the device. Additionally, elements in the drawings are not necessarily drawn to scale. For example, the dimensions of some of the elements in the drawings may be exaggerated relative to other elements to help improve understanding of embodiments of the device. The same reference numerals in different drawings denote the same elements, while similar reference numerals may, but do not necessarily, denote similar elements.

### DETAILED DESCRIPTION

The following detailed description is exemplary in nature and is not intended to limit the device or the application and uses of the device. Furthermore, there is no intention to be bound by any theory presented in the preceding background of the device or the following detailed description.

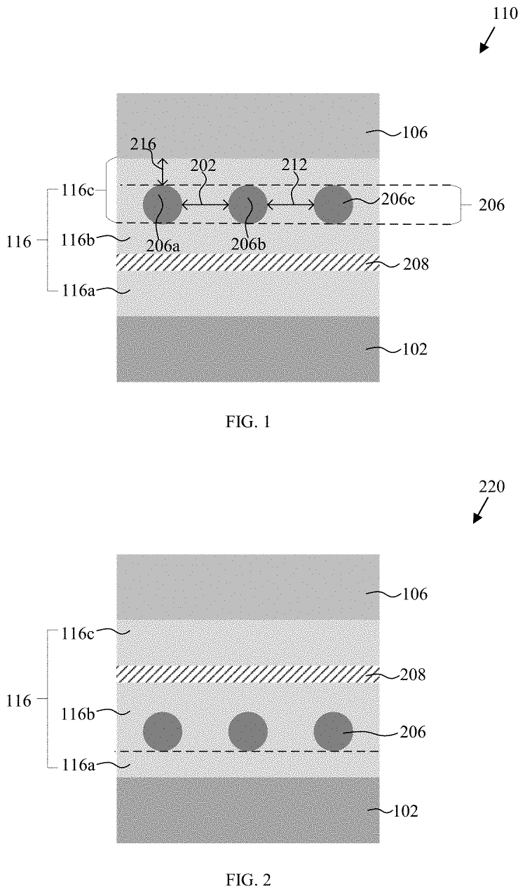

FIG. 1 is a cross-section view of a resistive memory device 110 according to an embodiment of the disclosure. The resistive memory device 110 includes a first electrode 102 having a first work function and a second electrode 106 having a second work function, wherein the first work function is different from the second work function. The difference between the work function of the first electrode 102 and the work function of the second electrode 106 may be larger than 0.05 eV. A larger difference between the work function of the first electrode 102 and of the second electrode 106 results in a larger difference between the high and low resistance states.

The dielectric layers 116a, 116b and 116c (collectively referred to as dielectric layer 116) are disposed between the first electrode 102 and the second electrode 106. A set of nanocrystal structures 206 is distributed in a dielectric layer 116c. A conductive layer 208 is disposed between the set of nanocrystal structures 206 and the first electrode 102. In a preferred embodiment, the conductive layer 208 may be a metal layer. A dielectric layer 116a is disposed between the conductive layer 208 and the first electrode 102. A dielectric layer 116b is disposed between the set of nanocrystal structures 206 and the conductive layer 208.

In an aspect of the present disclosure, the set of nanocrystal structures 206 is separated from the second electrode 106 by a distance 216 ranging from 3 to 20 nm. In another aspect of the present disclosure, the set of nanocrystal structures 206 has at least three nanocrystals, a first nanocrystal 206a, a second nanocrystal 206b and a third nanocrystal 206c. The first nanocrystal 206a is separated from the second nanocrystal 206b by the dielectric layer 116. The second nanocrystal 206b is separated from the third nanocrystal 206c by the dielectric layer 116. The separation distance 202 between the first nanocrystal 206a and the second nanocrystal 206b may or may not be equal to the separation distance 212 between the second nanocrystal 206b and the third nanocrystal 206c.

In an embodiment of the disclosure, the first nanocrystal 206a, the second nanocrystal 206b and the third nanocrystal 206c are spherical in shape. In another embodiment, the nanocrystal structures 206 are elliptical in shape. The shape of the nanocrystal structures 206 is representative and not intended to be limiting.

The resistive memory device 110 is fabricated by depositing a layer of metal having a first work function to form a first electrode 102. A dielectric layer 116a is subsequently deposited on the first electrode 102. A conductive layer 208 is formed on the dielectric layer 116a by depositing a layer of metal. A dielectric layer 116b is deposited on the conductive layer 208. A set of nanocrystal structures 206 is formed on the dielectric layer 116b. A dielectric layer 116c is deposited on the set of nanocrystal structures 206. Hence, the set of nanocrystal structures 206 is distributed in the dielectric layer 116c. A layer of metal having a second work function is deposited on the dielectric layer 116c to form the second electrode 106.

The set of nanocrystal structures 206 is formed by depositing a layer of metal on the dielectric layer 116b followed by annealing the layer of metal. In an aspect of the disclosure, the dielectric layer 116c is deposited together with the deposition of the layer of metal. In another aspect of the disclosure, the dielectric layer 116c is deposited after the metal deposition. For example, a layer of metal with a thickness in the range of 2 to 5 nm is deposited on the dielectric layer 116b. The deposited layer of metal is annealed at a temperature high enough to melt the metal layer. Hence, the annealing temperature range varies with the type of metal deposited. After annealing, the melted layer of metal join together to form the nanocrystal structures due to strain.

The first electrode 102 and the second electrode 106 of the resistive memory device 110 are connected to peripheral circuitry such as row and column address decoders. The first electrode 102 of the resistive memory device 110 is connected to a drain of an n-channel metal oxide semiconductor (NMOS) access transistor.

The first electrode 102 and the second electrode 106 comprise aluminum, titanium, tungsten, ruthenium, nickel, copper, silver, iridium, platinum, gold and tantalum. The electrodes may be fabricated by physical vapor deposition (PVD), chemical vapor deposition (CVD) or atomic layer deposition (ALD).

The set of nanocrystal structures 206 and the conductive layer 208 comprise aluminum, titanium, tungsten, ruthenium, nickel, copper, silver, iridium, platinum, gold, tantalum, cobalt, terbium, dysprosium, holmium and gadolinium. The nanocrystal structures 206 and the conductive layer 208 may be fabricated by PVD, CVD or ALD. Preferred fabrication methods for the nanocrystal structures are by PVD or CVD.

The dielectric layer 116 comprise a binary oxide of magnesium, silicon, aluminum, chromium, manganese, iron, cobalt, zinc, germanium, titanium, nickel, copper, yttrium, zirconium, niobium, molybdenum, tin, lanthanum, hafnium, tantalum, tungsten, cerium, gadolinium, ytterbium and lutetium. For example, the dielectric layer 116 includes aluminum oxide. The dielectric layer 116 may be fabricated by PVD, CVD or ALD.

The resistive memory device 110 as illustrated in FIG. 1 may be modified to create alternative embodiments within the scope of this disclosure. For example, FIG. 2 is a cross section view of a resistive memory device 220 according to another embodiment of the disclosure. The same reference numbers used in FIG. 1 are also used in FIG. 2 for identical features.

As shown in FIG. 2, the positions of nanocrystal structures 206 and conductive layer 208 are switched, as compared with resistive memory device 110. The resistive memory device 220 is fabricated by depositing a layer of metal having a first work function to form a first electrode 102. A first dielectric layer 116a is subsequently deposited on the first electrode 102. A set of nanocrystal structures 206 is formed on the first dielectric layer 116a. A second dielectric layer 116b is deposited on the set of nanocrystal structures 206. A layer of metal is deposited on the second dielectric layer 116b to form a conductive layer 208. A third dielectric layer 116c is deposited on the conductive layer 208. A layer of metal having a second work function is deposited on the third dielectric layer 116c to form the second electrode 106.

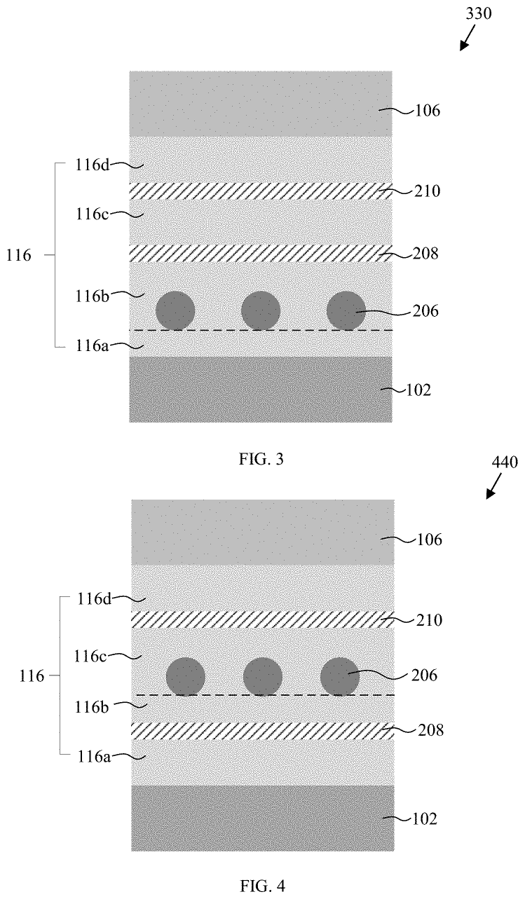

FIG. 3 is a cross section view of a resistive memory device 330 according to yet another embodiment of the disclosure. The same reference numbers used in FIG. 2 are also used in FIG. 3 for identical features.

As shown in FIG. 3, the resistive memory device 330 includes additional layers such as a second conductive layer 210 and a fourth dielectric layer 116d as compared to FIG. 2. The resistive memory device 330 is fabricated by depositing a layer of metal having a first work function to form a first electrode 102. A first dielectric layer 116a is deposited on the first electrode 102. A set of nanocrystal structures 206 is formed on the first dielectric layer 116a. A second dielectric layer 116b is deposited on the set of nanocrystal structures 206. A layer of metal is deposited on the second dielectric layer 116b to form a first conductive layer 208. A third dielectric layer 116c is deposited on the first conductive layer 208. A second layer of metal is deposited on the third dielectric layer 116c to form a second conductive layer 210. A fourth dielectric layer 116d is deposited on the second conductive layer 210. A layer of metal having a second work function is deposited on the fourth dielectric layer 116d to form a second electrode 106.

FIG. 4 is a cross-section view of a resistive memory device 440 according to another embodiment of the disclosure. The same reference numbers used in FIG. 3 are also used in FIG. 4 for identical features.

As shown in FIG. 4, the set of nanocrystal structures 206 is disposed between the first conductive layer 208 and the second conductive layer 210. In comparison, FIG. 3 shows the set of nanocrystal structures 206 being disposed below both the first conductive layer 208 and the second conductive layer 210. The resistive memory device 440 is fabricated by depositing a layer of metal having a first work function to form a first electrode 102. A first dielectric layer 116a is deposited on the first electrode 102. A layer of metal is deposited on the first dielectric layer 116a to form a first conductive layer 208. A second dielectric layer 116b is deposited on the first conductive layer 208. Subsequently, a set of nanocrystal structures 206 is formed on the second dielectric layer 116b. A third dielectric layer 116c is deposited on the set of nanocrystal structures 206. A second layer of metal is deposited on the third dielectric layer 116c to form a second conductive layer 210. A fourth dielectric layer 116d is deposited on the second conductive layer 210. A layer of metal having a second work function is deposited on the fourth dielectric layer 116d to form a second electrode 106.

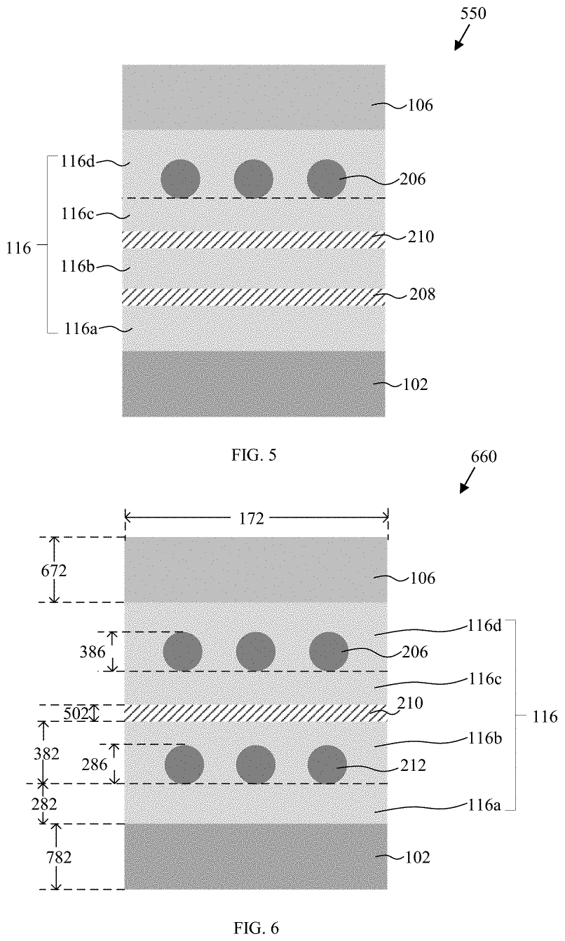

FIG. 5 is a cross-section view of a resistive memory device 550 according to yet another embodiment of the disclosure. The same reference numbers used in FIG. 4 are also used in FIG. 5 for identical features.

As shown in FIG. 5, the set of nanocrystal structures 206 is disposed above both the first conductive layer 208 and the second conductive layer 210. In comparison, FIG. 4 shows the set of nanocrystal structures 206 being disposed between the first conductive layer 208 and the second conductive layer 210. The resistive memory device 550 is fabricated by depositing a layer of metal having a first work function to form a first electrode 102. A first dielectric layer 116a is deposited on the first electrode 102. A layer of metal is deposited on the first dielectric layer 116a to form a first conductive layer 208. A second dielectric layer 116b is deposited on the first conductive layer 208. A second layer of metal is deposited on the second dielectric layer 116b to form a second conductive layer 210. A third dielectric layer 116c is deposited on the second conductive layer 210. A set of nanocrystal structures 206 is formed on the third dielectric layer 116c. A fourth dielectric layer 116d is deposited on the set of nanocrystal structures 206. A layer of metal having a second work function is deposited on the fourth dielectric layer 116d to form a second electrode 106.

FIG. 6 is a cross-section view of a resistive memory device 660 according to an exemplary embodiment of the disclosure. The same reference numbers used in FIG. 5 are also used in FIG. 6 for identical features.

As shown in FIG. 6, the resistive memory device 660 features a conductive layer 210 disposed between two sets of nanocrystal structures 206 and 212. In comparison, FIG. 4 features a set of nanocrystal structures 206 disposed between two conductive layers 210 and 208. The resistive memory device 660 is fabricated by depositing a layer of metal having a first work function to form a first electrode 102. A first dielectric layer 116a is deposited on the first electrode 102. A first set of nanocrystal structures 212 is formed on the first dielectric layer 116a. A second dielectric layer 116b is deposited on the first set of nanocrystal structures 212. A layer of metal is deposited on the second dielectric layer 116b to form a conductive layer 210. A third dielectric layer 116c is deposited on the conductive layer 210. A second set of nanocrystal structures 206 is formed on the third dielectric layer 116c. A fourth dielectric layer 116d is deposited on the second set of nanocrystal structures 206. A layer of metal having a second work function is deposited on the fourth dielectric layer 116d to form a second electrode 106.

Referring to FIG. 6, the first electrode 102 and the second electrode 106 have thicknesses 782 and 672, respectively, with a range between 10 to 100 nm. The first set of nanocrystal structures 212 and the second set of nanocrystal structures 206 have diameters 286 and 386, respectively, with a range between 2 to 5 nm. The conductive layer 210 has a thickness 502 with a range between 1 to 5 nm. The dielectric layer 116a has a thickness 282 with a range between 3 to 20 nm. The dielectric layer 116b has a thickness 382 with a range between 5 to 25 nm. The resistive memory device 660 has a length 172 with a range between 5 nm and 1 μm.

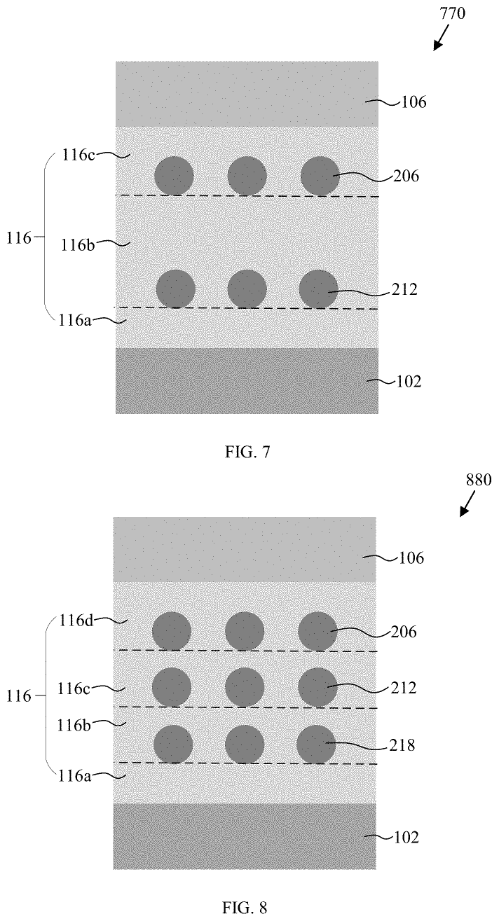

FIG. 7 is a cross-section view of a resistive memory device 770 according to an embodiment of the disclosure, which has a conductive layer that is a set of nanocrystal structures rather than a metal layer. The same reference numbers used in FIG. 6 are also used in FIG. 7 for identical features.

The resistive memory device 770 is fabricated by depositing a layer of metal having a first work function to form a first electrode 102. A first dielectric layer 116a is deposited on the first electrode 102. A first set of nanocrystal structures 212 is formed on the first dielectric layer 116a. A second dielectric layer 116b is deposited on the first set of nanocrystal structures 212. A second set of nanocrystal structures 206 is formed on the second dielectric layer 116b. A third dielectric layer 116c is deposited on the second set of nanocrystal structures 206. A layer of metal having a second work function is deposited on the third dielectric layer 116c to form a second electrode 106.

In an aspect of the disclosure, having a conductive layer that is a set of nanocrystal structures rather than a metal layer reduces variability in the switching voltages or set and reset voltages as the conductive filament formation occurs only at particular locations in the device. For example, the conductive filaments are formed between the first electrode 102 and the nanocrystals in the first set of nanocrystal structures 212. In addition, conductive filaments are also formed between the nanocrystals in the first set of nanocrystal structures 212 and the second set of nanocrystal structures 206. Furthermore, conductive filaments are formed between the second set of nanocrystal structures 206 and the second electrode 106.

In another aspect of the disclosure, having a conductive layer that is either a set of nanocrystal structures or a metal layer also improves the device lifetime due to formation of shorter filaments.

FIG. 8 is a cross-section view of a resistive memory device 880 according to another embodiment of the disclosure. The same reference numbers used in FIG. 7 are also used in FIG. 8 for identical features.

As shown in FIG. 8, the resistive memory device 880 has an additional set of nanocrystal structures 218 as compared to FIG. 7. The resistive memory device 880 is fabricated by depositing a layer of metal having a first work function to form a first electrode 102 and depositing a first dielectric layer 116a on the first electrode 102. A first set of nanocrystal structures 218 is formed on the first dielectric layer 116a. A second dielectric layer 116b is deposited on the first set of nanocrystal structures 218. A second set of nanocrystal structures 212 is formed on the second dielectric layer 116b. A third dielectric layer 116c is deposited on the second set of nanocrystal structures 212. A third set of nanocrystal structures 206 is formed on the third dielectric layer 116c. A fourth dielectric layer 116d is deposited on the third set of nanocrystal structures 206. A layer of metal having a second work function is deposited on the fourth dielectric layer 116d to form a second electrode 106.

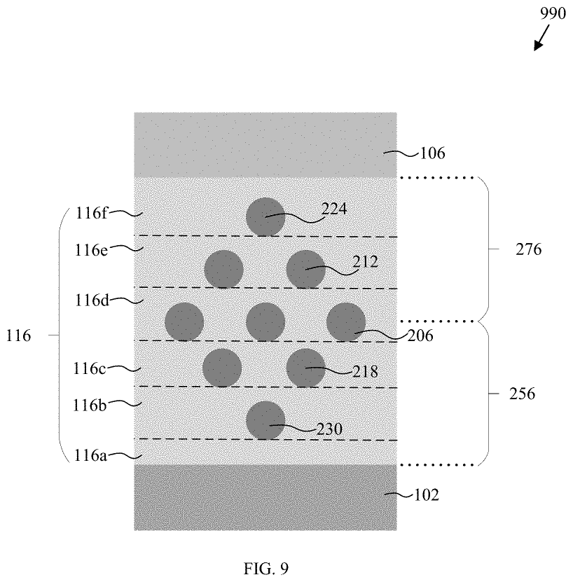

FIG. 9 is a cross-section view of a resistive memory device 990 according to yet another embodiment of the disclosure, which has a plurality of conductive layers. As shown in FIG. 9, the conductive layers are sets of nanocrystal structures. The same reference numbers used in FIG. 8 are also used in FIG. 9 for identical features.

The resistive memory device 990 is fabricated by depositing a layer of metal having a first work function to form a first electrode 102 and depositing a first dielectric layer 116a on the first electrode 102. A first conductive layer 230 may be a first set of nanocrystal structures that is formed on the first dielectric layer 116a. The first set of nanocrystal structures has at least one nanocrystal. The number of nanocrystals in the first set of nanocrystal structures is varied by controlling the amount of metal deposited to form the nanocrystals. A second dielectric layer 116b is deposited on the first conductive layer 230. A second conductive layer 218 may be a second set of nanocrystal structures that is formed on the second dielectric layer 116b. The second set of nanocrystal structures has at least two nanocrystals. A third dielectric layer 116c is deposited on the second conductive layer 218. A third conductive layer 206 may be a third set of nanocrystal structures that is formed on the third dielectric layer 116c. The third set of nanocrystal structures has at least three nanocrystals and in a representative middle layer.

Subsequently, a fourth dielectric layer 116d is deposited on the third conductive layer 206. A fourth conductive layer 212 may be a fourth set of nanocrystal structures that is formed on the fourth dielectric layer 116d. The fourth set of nanocrystal structures has at least two nanocrystals. A fifth dielectric layer 116e is deposited on the fourth conductive layer 212. A fifth conductive layer 224 may be a fifth set of nanocrystal structures that is formed on the fifth dielectric layer 116e. The fifth set of nanocrystal structures has at least one nanocrystal. A sixth dielectric layer 116f is deposited on the fifth conductive layer 224. Finally, a layer of metal having a second work function is deposited on the sixth dielectric layer 116f to form the second electrode 106.

The number of nanocrystals in the first, second, third, fourth and fifth sets of nanocrystal structures is representative and is not supposed to be limiting. As shown, the number of nanocrystals increases with increasing distance from the first electrode 102 within a first section 256 in the dielectric layer 116 up to the middle layer 116d. Thereafter, the number of nanocrystals decreases with increasing distance from the first electrode 102 within a second section 276 in the dielectric layer 116. The first section 256 and the second section 276 have substantially similar thicknesses. In another aspect of the present disclosure, the second, third and fourth conductive layers, 218, 206 and 212, respectively, may alternatively be metal layers (not shown).

Referring to FIG. 9, the resistive memory device 990 features the number of conducting filaments formed between the first electrode 102 and the second electrode 106 being controlled and minimized near each electrode. For example, conducting filaments are formed between the first electrode 102 and the first set of nanocrystal structures 230. Additional conducting filaments are also formed between the first set of nanocrystal structures 230 and the second, third, fourth, fifth sets of nanocrystal structures as well as the second electrode 106. The number of conducting filaments formed between the fourth set of nanocrystal structures 212 and the fifth set of nanocrystal structures 224 is less than the number of conducting filaments formed between the third set of nanocrystal structures 206 and the fourth set of nanocrystal structures 212. The control and minimization of the number of conducting filaments formed results in improved device performance, such as longer device lifetime and tighter distributions in switching voltages.

The terms “first”, “second”, “third”, and the like in the description and in the claims, if any, are used for distinguishing between similar elements and not necessarily for describing a particular sequential or chronological order. It is to be understood that the terms so used are interchangeable under appropriate circumstances such that the embodiments of the device described herein are, for example, capable of operation in sequences other than those illustrated or otherwise described herein. The terms “left”, “right”, “front”, “back”, “top”, “bottom”, “over”, “under”, and the like in the description and in the claims, if any, are used for descriptive purposes and not necessarily for describing permanent relative positions. It is to be understood that the terms so used are interchangeable under appropriate circumstances such that the embodiments of the device described herein are, for example, capable of operation in other orientations than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method. Furthermore, the terms “comprise”, “include”, “have”, and any variations thereof, are intended to cover a non-exclusive inclusion, such that a process, method, article, or device that comprises a list of elements is not necessarily limited to those elements, but may include other elements not expressly listed or inherent to such process, method, article, or device. Occurrences of the phrase “in one embodiment” herein do not necessarily all refer to the same embodiment.

While several exemplary embodiments have been presented in the above detailed description of the device, it should be appreciated that number of variations exist. It should further be appreciated that the embodiments are only examples, and are not intended to limit the scope, applicability, dimensions, or configuration of the device in any way. Rather, the above detailed description will provide those skilled in the art with a convenient road map for implementing an exemplary embodiment of the device, it being understood that various changes may be made in the function and arrangement of elements and method of fabrication described in an exemplary embodiment without departing from the scope of this disclosure as set forth in the appended claims.

What is claimed is:

1. A resistive memory device comprising:
a first electrode having a first work function;
a second electrode having a second work function, wherein the first work function is different from the second work function;
a dielectric layer disposed between the first and second electrodes;
a set of nanocrystal structures distributed in the dielectric layer; and
a conductive layer disposed in the dielectric layer.

2. The resistive memory device of claim 1, wherein the set of nanocrystal structures is a first set of nanocrystal structures and the conductive layer is a second set of nanocrystal structures.

3. The resistive memory device of claim 1, wherein the conductive layer is a metal layer.

4. The resistive memory device of claim 2 further comprising a third set of nanocrystal structures distributed in the dielectric layer.

5. The resistive memory device of claim 2 further comprising a metal layer disposed in the dielectric layer.

6. The resistive memory device of claim 3, further comprising a second metal layer disposed in the dielectric layer.

7. The resistive memory device of claim 4 further comprising:
a fourth set of nanocrystal structures distributed in the dielectric layer and
a fifth set of nanocrystal structures distributed in the dielectric layer;
wherein the first and fifth sets of nanocrystal structures have at least one nanocrystal structure, the second and fourth sets of nanocrystal structures have at least two nanocrystal structures, and the third set of nanocrystal structures has at least three nanocrystal structures; and
wherein the first, second, third, fourth and fifth sets of nanocrystal structures are sequentially disposed in the dielectric layer between the first and second electrodes.

8. A resistive memory device comprising:
a first electrode;
a second electrode;
a dielectric layer disposed between the first and second electrodes;
at least one set of nanocrystal structures horizontally distributed in the dielectric layer; and
a conductive layer horizontally disposed in the dielectric layer.

9. A method to fabricate a resistive memory device, the method comprising:
depositing a layer of metal having a first work function to form a first electrode;
depositing a first dielectric layer on the first electrode;
forming a first conductive layer on the dielectric layer;
depositing a second dielectric layer on the first conductive layer;
forming a second conductive layer on the second dielectric layer;
depositing a third dielectric layer on the second conductive layer;
depositing a layer of metal having a second work function over the third dielectric layer to form a second electrode, wherein the first work function is different from the second work function.

10. The method of claim 9, wherein the formation of the first conductive layer further comprises forming a set of nanocrystals structures.

11. The method of claim 9, wherein the formation of the first conductive layer further comprises depositing a layer of metal.

12. The method of claim 10, wherein the formation of the second conductive layer further comprises forming a second set of nanocrystal structures.

13. The method of claim 10, wherein the formation of the second conductive layer further comprises depositing a layer of metal.

14. The method of claim 11, wherein the formation of the second conductive layer comprises forming a set of nanocrystal structures.

15. The method of claim 12 further comprising:
forming a third set of nanocrystal structures on the third dielectric layer prior to the formation of the second electrode and
depositing a fourth dielectric layer on the third set of nanocrystal structures.

16. The method of claim 15 further comprising:
forming a fourth set of nanocrystal structures on the fourth dielectric layer prior to the formation of the second electrode;
depositing a fifth dielectric layer on the fourth set of nanocrystal structures;
forming a fifth set of nanocrystal structures on the fifth dielectric layer; and
depositing a sixth dielectric layer on the fifth set of nanocrystal structures, wherein the second electrode is formed on the sixth dielectric layer.

17. The method of claim 13 further comprising:
forming a second set of nanocrystal structures on the third dielectric layer prior to the formation of the second electrode; and
depositing a fourth dielectric layer on the second set of nanocrystal structures, wherein the second electrode is formed on the fourth dielectric layer.

18. The method of claim 13 further comprising:
depositing a second layer of metal on the third dielectric layer prior to the formation of the second electrode; and
depositing a fourth dielectric layer on the second layer of metal, wherein the second electrode is formed on the fourth dielectric layer.

19. The method of claim 14 further comprising:
depositing a second layer of metal on the third dielectric layer prior to the formation of the second electrode; and
depositing a fourth dielectric layer on the second layer of metal, wherein the second electrode is formed on the fourth dielectric layer.

20. The method of claim 11 wherein the formation of the second conductive layer further comprises depositing a second layer of metal;
forming a set of nanocrystal structures on the third dielectric layer prior to the formation of the second electrode; and
depositing a fourth dielectric layer on the set of nanocrystal structures, wherein the second electrode is formed on the fourth dielectric layer.
